(19) United States
(12) Patent Application Publication
(10) Pub. No.: US 2020/0347512 A1
(43) Pub. Date: Nov. 5, 2020

(54) SPINCOATING EPITAXIAL FILMS

(71) Applicant: The Curators of the University of Missouri, Columbia, MO (US)

(72) Inventor: Jay A. Switzer, Rolla, MO (US)

(73) Assignee: The Curators of the University of Missouri, Columbia, MO (US)

(21) Appl. No.: 16/398,430

(22) Filed: Apr. 30, 2019

(51) Int. Cl. C30B 19/12; C30B 19/08

(52) U.S. Cl. CPC C30B 19/12; C30B 29/12; C30B 19/08

(57) ABSTRACT

A process for forming an epitaxial film comprising spinning a substrate having an ordered crystal structure; heating the substrate during spinning to a temperature between 70° C. and 150° C.; dripping epitaxial film precursor solution onto the spinning substrate, where the precursor solution comprises inorganic film precursor material in a solvent; and continuing the heating and spinning to remove the solvent and epitaxially grow the epitaxial film on the substrate.

### STATEMENT OF GOVERNMENT INTEREST

This invention was made with Government support under U.S. Department of Energy contract DE-FG02-08ER46518. The Government may have certain rights in the invention.

### FIELD OF THE INVENTION

This invention relates to single crystal type films for use in applications such as electronic and optical devices including flexible electronics, displays, and solar cells which benefit from the properties of single crystal or highly ordered materials.

### BACKGROUND

Single crystal materials have excellent electronic and optical properties due to the absence of high-angle grain boundaries. Epitaxy is one technical approach to growing single crystal films. Epitaxy is the growth of crystals whose orientation is determined by their crystalline substrate. Epitaxy can produce thin films with atomic arrangement that mimics single crystals. Epitaxial growth is performed under ultrahigh vacuum or high temperatures by techniques such as molecular beam epitaxy, chemical vapor deposition, and liquid-phase epitaxy. There are also solution-based systems for deposition of epitaxial films such as hydrothermal processing, chemical bath deposition, and electrodeposition. Each of these solution-based methods has limitations. Hydrothermal processing requires high temperature and pressure. Chemical bath deposition requires specific reactions to occur at the substrate surface. Electrodeposition requires conducting or semiconducting substrates.

Ji et al., High-Performance Photodetectors Based on Solution-Processed Epitaxial Grown Hybrid Halide Perovskites, Nano Lett. 18, 994-1000 (2018), describes spincoating onto single crystal KCl in a system that requires crystallizing the as-deposited amorphous material into an epitaxial film with a final annealing step. There has also been previous work on the spincoating of amorphous sol-gel precursors for oxides onto single-crystal surfaces in a process that requires a high-temperature burn-off of organics.

There is therefore a continuing need for improved solution-based methods for forming materials with single crystal type behavior.

### SUMMARY OF THE INVENTION

Briefly, therefore, in one aspect the invention is directed to a process for forming an epitaxial film comprising spinning a substrate having an ordered crystal structure; heating the substrate during spinning to a temperature between 70° C. and 130° C.; dripping epitaxial film precursor solution onto the spinning substrate, where the precursor solution comprises inorganic film precursor material in a solvent; and continuing the heating and spinning to remove the solvent and epitaxially grow the epitaxial film on the substrate.

Other objects and features of the invention will be in part apparent and in part pointed out hereinafter.

### BRIEF DESCRIPTION OF THE FIGURES

FIG. 1 is a schematic depiction of the spincoating process of the invention.

FIG. 2 is an optical micrograph of two deposited films.

FIG. 3 is an SEM image of a deposited film.

FIG. 4 is an SEM image of a deposited film.

FIG. 5 is an SEM image of a deposited film.

FIG. 6 is an optical micrograph of a deposited film.

FIG. 7 is an SEM image of a deposited film.

FIG. 8 is pole figure illustration of a film and substrate processed according to the invention.

FIG. 9 is a pole figure illustration of a film and substrate processed according to the invention.

FIG. 10 is a pole figure illustration of a film and substrate processed according to the invention.

FIG. 11 is a pole figure illustration of a film and substrate processed according to the invention.

### DETAILED DESCRIPTION OF PREFERRED EMBODIMENTS

In accordance with this invention, an inorganic film having a highly ordered crystal structure is grown on a highly ordered substrate by spincoating under conditions that promote heterogeneous nucleation onto the substrate as opposed to homogeneous nucleation in bulk solution.

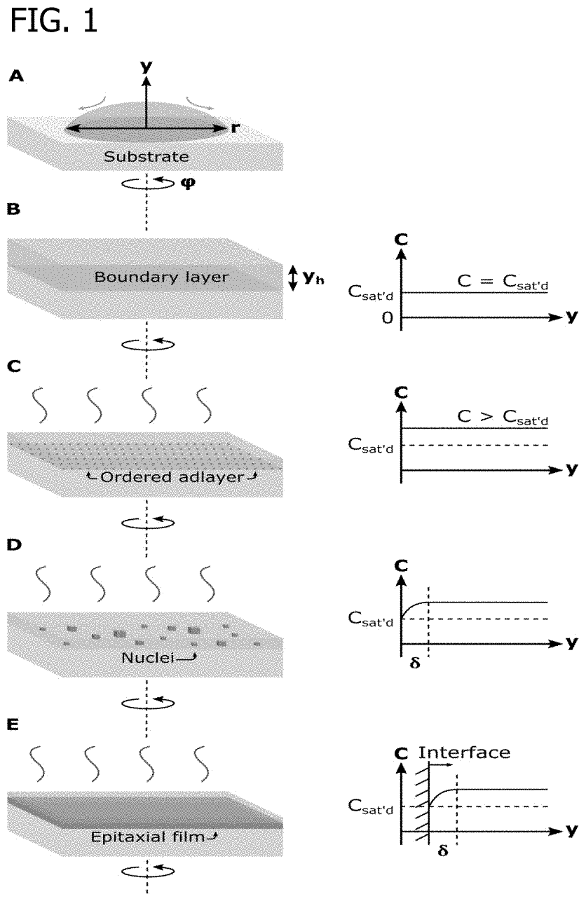

FIG. 1 shows the spincoating method of the invention schematically. In step (A), each precursor solution is dispensed on a room temperature or preheated single crystal or single-crystal-like substrate as it begins to spin. Step (B) shows that when the solution reaches the spin speed of the sample, a hydrodynamic boundary layer forms with thickness yₕ. In step (C), an ordered anion adlayer is believed to form at the substrate/solution interface, and the solution concentration reaches supersaturation due to evaporation. In step (D), nucleation occurs at the solution-substrate interface and a concentration gradient and diffusion layer form. In step (E), the nuclei grow into a film, and the interface between solution and substrate continues to shift until solvent evaporation is complete. Steps A through D are then typically repeated up to several times.

In one embodiment of the process of the invention, the material to be spincoated is an epitaxial film precursor material which, and an epitaxial film precursor solution of the material is dripped onto the substrate to initiate the spincoating process. In an alternative embodiment, the material to be deposited itself is not soluble, so a soluble precursor to the material is used, and that precursor is converted to the material by drying at elevated temperatures. The term “epitaxial film precursor solution” as used herein encompasses both situations. Examples of systems of soluble epitaxial film precursor material in solution are as follows: Pbl₂ in N,N-dimethylformamide (DMF) solution; CsPbBr₃ in dimethyl sulfoxide (DMSO) solution; NaCl in aqueous solution. One example of a system using a soluble precursor is spincoating ZnO from an aqueous ammonia solution of Zn(II). Other examples include precursors for metal sulfide semiconductor materials. For example, thiourea is added to an aqueous solution containing Pb or Cd ions and the solution heated, H₂S can be generated in situ and provide S for deposition of epitaxial PbS or CdS films. Films of Pbl₂, CsPbBr₃, ZnO, PbS, and CdS are functional materials that can serve as semiconductors in solar cell and LED applications. Epitaxial NaCl can serve as a water soluble template for large scale epitaxial lift-off of flexible single-crystal-like materials for electronics, solar cells, and displays. While the precursor materials are described in terms of compounds such as Pbl₂, CsPbBr₃, NaCl, PbBr₂, and CsBr and the epitaxial film precursor solutions are described as containing these materials or as being, e.g., “a CsPbBr₃ solution,” one skilled in the art will understand that this is on an equivalent basis, as the molecular components are disassociated in solution and the particular compounds themselves are not detectable as such.

The thickness of the as-deposited epitaxial film of the invention is not narrowly critical. In one embodiment, the film has a thickness in the range of about 5 nm to about 200 μm, for example, between about 1 μm and about 100 μm. Thickness is controlled by the solution concentration, spin rate, viscosity, and number of applications.

In accordance with this invention, the spincoating takes place onto a single crystal substrate, or a single-crystal-like substrate, or other highly ordered substrate. Examples include single crystal materials such as SrTiO₃ and mica. Other examples include proxies for single crystals, such as epitaxial Au or Ag on single crystal Si. The substrate is maintained at an elevated temperature during the spincoating. For example, in one embodiment, the substrate is maintained at a temperature between about 70° C. and 150° C., such as in the range of 70 to 130° C., such as 70 to 90° C., or 90 to 130° C. The purpose of heating the substrate is to facilitate epitaxial deposition out of solution. Without being bound to a particular theory, it is believed that by heating the substrate during the spincoating while the precursor ions are still in solution, the ions and other species have an increased mobility which promotes their diffusion to and deposition at locations and in orientations of lower energy. That is, it promotes highly ordered and epitaxial deposition. In one preferred embodiment, the heating is accomplished by preheating the substrate prior to dripping of solution onto the substrate, and then continual heating during spincoating. In another embodiment, the substrate is not preheated, but is heated during spinning of the substrate. In both instances, the substrate and adjacent solution are at elevated temperature as the solvent evaporates and the overall solution passes from undersaturation through to supersaturation, So the heating is initiated at least at a time prior to supersaturation; i.e., prior to nucleation. This promotes the invention's epitaxial deposition at the solid/solution interface. This is heterogeous nucleation oriented under influence of the orientation of the substrate. This is in contrast to other systems where nucleation is homogeneous and the deposition is either polycrystalline or amorphous because it is not heavily influenced by the crystal structure of the substrate. The process of the invention therefore produces a film that is epitaxial as-deposited, in contrast to films which are polycrystalline or amorphous as deposited and must be subjected to an anneal or other operation to impart an epitaxial, ordered, single crystal, or single crystal like structure. In other words, the deposition mechanism and the deposited film are innately epitaxial and epitaxial ab initio.

The solution may optionally be at an elevated temperature at the time it is dripped onto the spinning substrate. For example, the applied solution may be at a temperature between 70 and 150° C., such as between 75 and 100° C. or between 120 and 140° C. The purpose of heating the solution is to further promote mobility of ions and other species at the substrate/solution interface as the spinning system passes from undersaturation through to supersaturation.

The spin rate of the substrate is at least about 300 rpm, such as 400 to 3500 rpm. In some embodiments the substrate is rotated at a lower speed (e.g., 500 rpm) and then rotated at a higher speed (e.g., 3000 rpm). The spin time is at least about 20 seconds, more typically between 25 seconds and 180 seconds.

A critical aspect of the present invention is that the spinning and heating of the substrate promote growth of the epitaxial film which has its highly ordered crystal structure imparted during the solvent evaporation and film growth process, such that there is no need for any high temperature anneal or other high temperature process. The maximum temperature to which the growing film is exposed is the 70 to 150° C. of the heated substrate. In other words, the only heat input into the entire process is the heating of the substrate. Alternatively, the only heat input in the entire process is the heating of the substrate and the heating of the deposition solution prior to dripping on the substrate.

Without being bound to a particular theory, it is believed that a hydrodynamic boundary layer forms as shown in FIG. 1 followed by evaporation of solvent. A drop of solution spins and forms a stagnant hydrodynamic boundary layer. An ordered adlayer that lowers activation energy also forms. The solution reaches supersaturation due to evaporation of solvent resulting from the heating of the substrate and the rotation of the substrate. A concentration gradient forms that is a driving force for diffusion as shown at image D in FIG. 1, which then leads to epitaxial growth.

### EXAMPLES

The method of the invention was performed by spincoating to form films of Pbl₂, ZnO, CsPbBr₃, and NaCl.

Epitaxial Au(111) on Si(111) was used as an ordered substrate for spincoating of Pbl₂ and ZnO. Epitaxial Au(100) on Si(100) was used for spincoating of CsPbBr₃ and NaCl. To prepare the substrates, Si wafers with [111] and [100] orientations were obtained from Virginia Semiconductors Inc. The phosphorus doped n-Si(111) was miscut 0.2° towards [112] with a resistivity of 1.15Ω-cm. The n⁺⁺-Si(100) was degenerately doped with phosphorus with a resistivity of 0.001 Ω-cm. Each wafer was sliced into pieces with an area between about 0.5 cm² to 2 cm². InGa eutectic was scratched into the back of each Si piece with a diamond scriber and soldering iron to form an ohmic contact. Silver wire with silver paste (GC electronics, silver print II) was used to make an electrical back contact for both orientations. A polish made from Apiezon wax W dissolved in toluene (1 g of Apiezon per 1 ml of toluene) was applied to the back of Si to insulate the back contact. Both Si orientations were etched in 5% hydrofluoric acid for 30 seconds to dissolve the native oxide layer and to produce a hydrogen-terminated surface before Au deposition. All depositions were performed immediately after the etching process to avoid any surface passivation. Au was electrodeposited from a plating solution containing 0.1 mM HAuCl₄, 1 mM KCl, 1 mM H₂SO₄, and 100 mM K₂SO₄ in deionized (DI) water. The solution was prepared by adding 10 mL of a stock solution containing 1 mM HAuCl₄, 10 mM KCl, and 10 mM H₂SO₄ to 90 mL of DI water and 100 mM K₂SO₄. Each Si substrate was pre-polarized at −1.9 V vs. Ag/AgCl before immersing into the solution to prevent both oxide formation and Au polycrystalline electroless deposition. All Au depositions ranged from 10-30 minutes, using a Ag/AgCl reference electrode and an Au coil as a high surface area counter electrode, and were stirred at 200 rpm at room temperature. After each deposition, the samples were rinsed with DI water and dried in air.

In one embodiment, CsPbBr₃ was spincoated on single crystal SrTiO₃(100) and Mica(001) substrates. Single crystal SrTiO₃(100) samples with dimensions 10 mm×10 mm×0.5 mm were purchased from MTI Corporation. The highest grade V1 Mica(001) disc with a diameter of 20 mm was obtained from Ted Pella Inc. All the single crystals were used as received without any surface treatment.

Spincoating was performed using a programmable high-speed spincoater with in situ substrate heating capability purchased from MTI Corporation (VTC-100PA-HCHS). The heating accessory can quickly reach up to 120° C. using a tungsten-halogen lamp and is measured with a K-type thermocouple.

The CsPbBr₃ solution was prepared by dissolving 0.175 M PbBr₂ and 0.262 M CsBr (1:1.5 molar ratio) in dimethyl sulfoxide (DMSO) solution. The solution was stirred on a hot plate at 130° C. for 1 hour to obtain a clear solution before spincoating. The substrate—SrTiO₃(100), Mica(001), Au/Si(111), or Au/Si(100)—was quickly preheated to 110° C. and spun at 2000 rpm for 2 minutes. During the first 5 seconds of the rotation, 250 μL of CsPbBr₃ solution was dispensed on the hot substrate using a volume-controlled pipette.

The Pbl₂ solution was prepared by dissolving 1 M Pbl₂ in dimethylformamide (DMF). The solution was stirred on a hot plate at 80° C. for 1 hour to obtain a clear yellow solution before spincoating. The Au/Si(111) substrate was preheated to 80° C. and spun at 2000 rpm for 2 minutes. During the first 5 seconds of the rotation, 200 μL of Pbl₂ solution was dispensed on the hot substrate using a volume-controlled pipette.

The NaCl solution was prepared by adding NaCl to DI water until saturation was reached at room temperature. An epitaxial Ag(100) film was made by electrodepositing on a Au(100) film on Si(100). The Ag film was electrodeposited at a constant potential of −2.3 V vs. Hg/Hg₂SO₄ for 5 minutes in an acetate bath containing 0.1 mM AgAc, 1 mM KAc, 1 mM H₂SO₄ and 0.1 M K₂SO₄. Before rotating, 100 μL of NaCl solution was dispensed on the substrate using a volume-controlled pipette. Immediately after dispensing the solution, the spincoater was ramped to 500 rpm for 15 seconds followed by 2000 rpm for 45 seconds with in-situ heating at 100° C.

The ZnO solution was prepared by adding 130 mM of ZnO to an ammonium hydroxide solution with a 28-30% NH₃ basis (Sigma Aldrich). The solution was stirred overnight while sitting on a 0° C. cooling plate and filtered with a 0.45 μm PES filter (Whatman). Ethanol (40% by volume) was then added to the solution to aid in wetting the sample surface. The Au(111) substrate was preheated to 120° C. and spun at 3000 rpm for 30 seconds. During the first 5 seconds of rotation, 150 μL of ZnO solution was dispensed on the hot substrate with a volume controlled pipette.

TABLE I
SPINCOATING PARAMETERS

| | | | | Spin | Spin |
|---|---|---|---|---|---|
| | | Solution | Sample | rate | time |
| | Solution | Temp | Temp | rpm | seconds |
| CsPbBr₃ | .175 M PbRr₂ | 130 °C. | Preheated | 2000 | 120 |
| | .262 M CsBr | | to 110 °C. | | |
| | in DMSO | | | | |
| PbI₂ | 1 M PbI₂ | 80 °C. | Preheated | 2000 | 120 |
| | in DMF | | to 80 °C. | | |
| NaCI | Sat'd NaCI | RT | in situ | 500 | 15 |
| | Aqueous | | 100 °C. | 2000 | 45 |
| ZnO | 60% Sat'd | RT | Preheated | 3000 | 30 |

| | | |
|---|---|---|
| ZnO in | to 120° C. | 10 |
| ammonia | | repetitions |
| 40% ethanol | | |

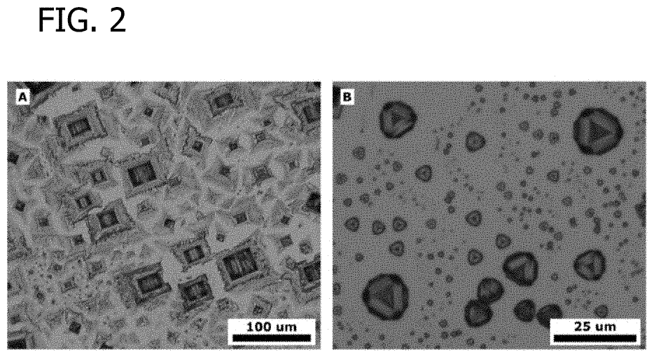

All of the foregoing samples were then analyzed without further processing. FIG. 2 shows plan-view optical microscope images (HiRox Digital Microscope KH-8700) of a deposited NaCl film. Image A shows NaCl on Ag(110)/Au(110)/Si(110). Image B shows NaCl on Ag(111)/Au(111)/Si(111). These micrographs show the NaCl orientation is directed by the single-crystal-like Ag substrate.

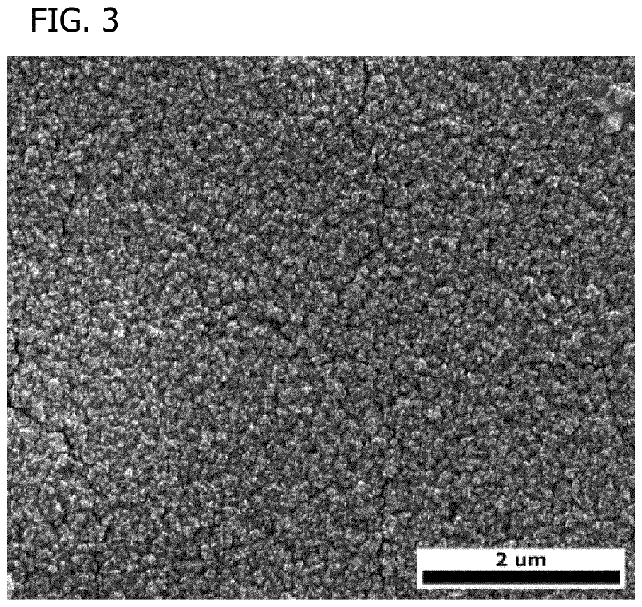

FIG. 3 shows an SEM image obtained with a Helios NanoLab DualBeam electron microscope using an accelerating voltage of 15-20 kV and beam current of 43 pA or 0.17 nA. The specimen is ZnO on Au/Si(111) and demonstrates that a dense film has formed after 10 repetitions of the spincoating process.

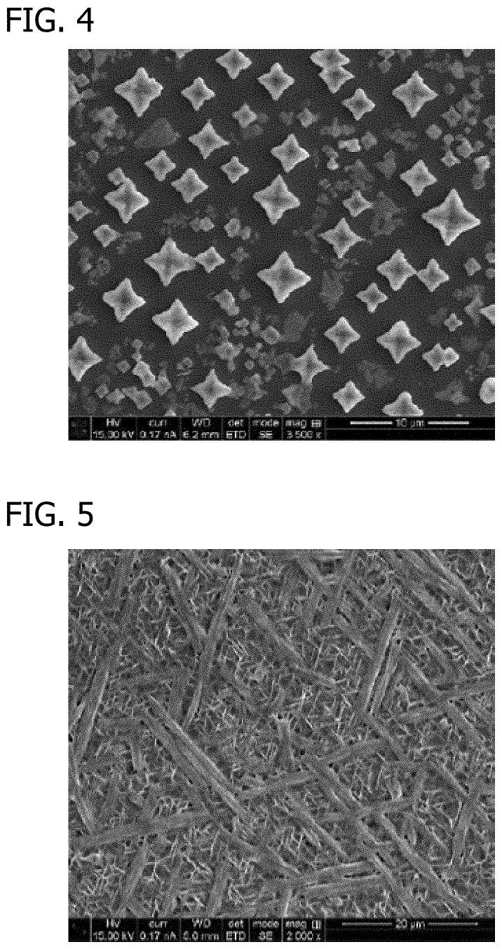

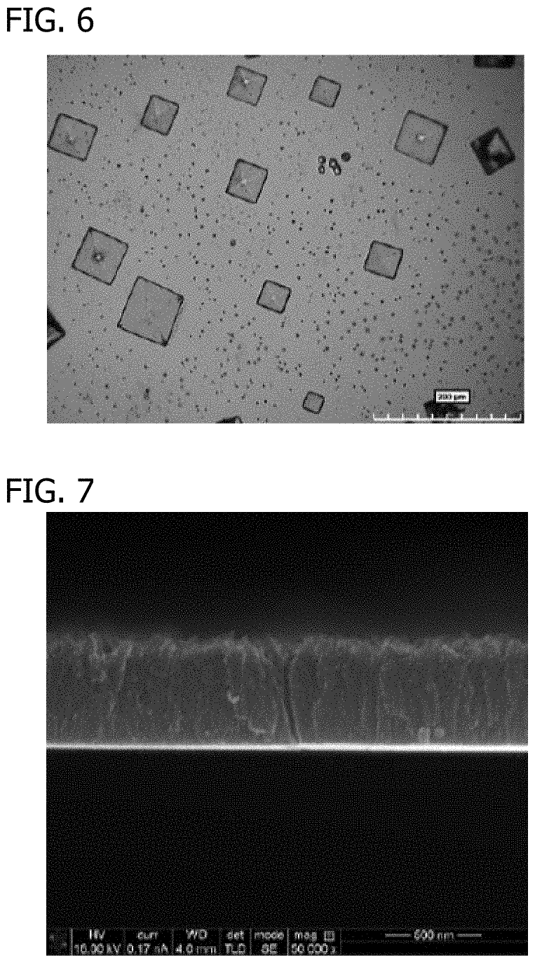

FIG. 4 is an SEM micrograph of CsPbBr₃ on SrTiO₃(100), and shows that the material deposits with a diamond-like morphology. FIG. 5 is an SEM micrograph of Pbl₂ on Au/Si(111), and shows a mesh-like morphology with the expected three-fold symmetry of the Au(111) substrate. FIG. 6 is an optical micrograph of NaCl on Ag/Au/Si(100) and shows the NaCl deposits as perfectly aligned cubes. FIG. 7 is an SEM cross section of ZnO on Au/Si(111).

X-Ray diffraction measurements were made with a Philips X'Pert Materials Research Diffractometer with Cu Kai radiation source (λ=1.54056 A). All 2theta-omega (out-of-plane orientation) scans were done using a 2-bounce hybrid monochromator with a Ge 220 monochromator and Ni 0.125 mm automatic beam attenuator and a 0.18° parallel plate collimator diffracted beam optics. Pole figures were measured using a crossed slit collimator with 2 mm divergence slit and 2 mm mask with a Ni filter and a 0.27° parallel plate collimator.

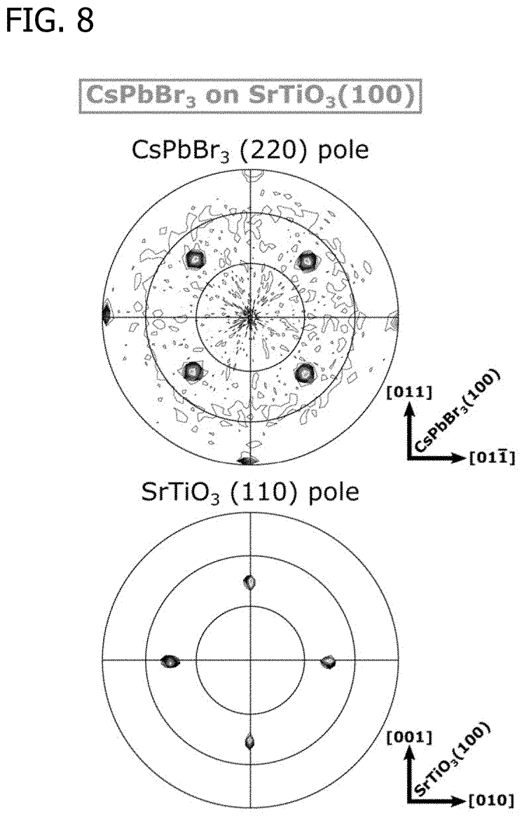

FIGS. 8 through 11 show pairs of pole figures for film / substrate systems made according to the invention. FIG. 8 shows a (220) pole figure of CsPbBr₃ (A) over a (110) pole figure of SrTiO₃(100) (B) and demonstrates that the CsPbBr₃ is epitaxial with a 45° in-plane rotation from the SrTiO₃ substrate on which it was deposited. The sharpness of the spots in the film images and their alignment with the spots in the substrate images show that the films are highly ordered and epitaxial with respect to the substrates. The radial grid lines represent 30° increments of the tilt angle.

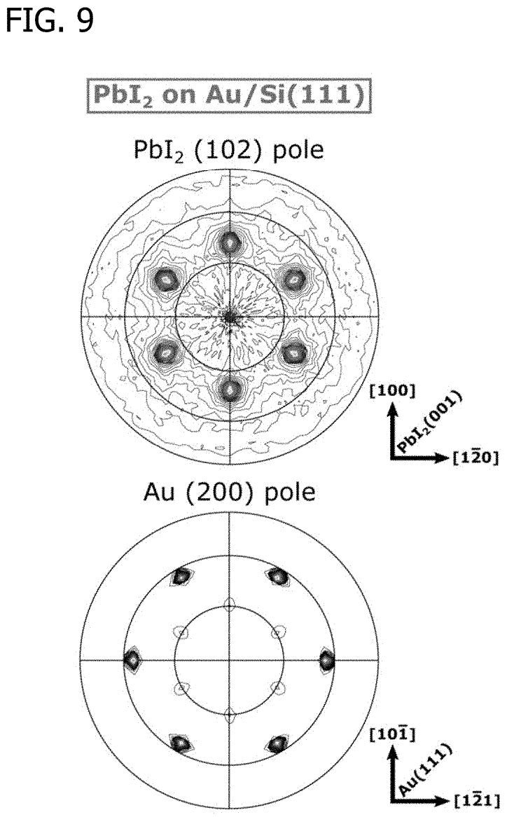

FIG. 9 shows a (102) pole figure of Pbl₂ (C) and (200) pole figure of Au(111) (D) film show that Pbl₂ is epitaxial with a 30° in-plane rotation from Au.

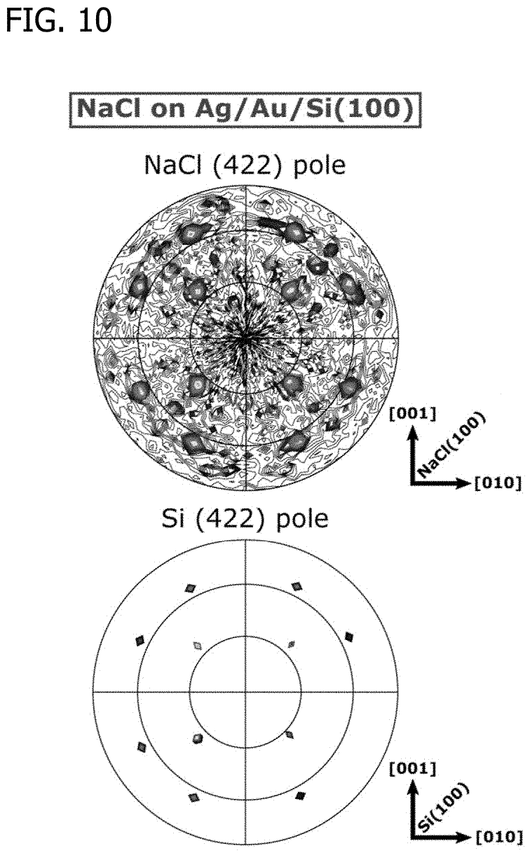

FIG. 10 shows a (422) pole figure of NaCl (E) and (422) pole of Si(100) (F) substrate show that NaCl is epitaxial with no in-plane rotation.

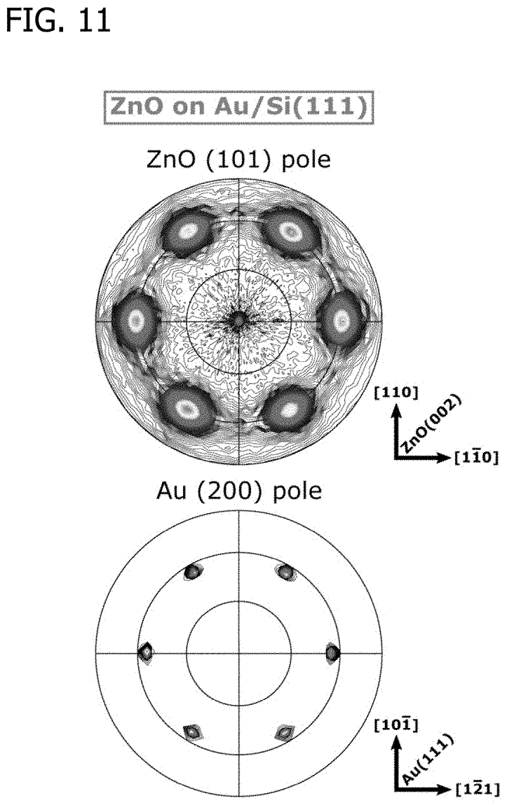

FIG. 11 shows a (101) pole of ZnO (G) and (200) pole of Au(111) (H) film show that ZnO is epitaxial with no in-plane rotation.

These results demonstrate that spincoating of epitaxial films offers an inexpensive and readily accessible route to single-crystal-like materials that should exhibit superior electronic and optical properties due to the absence of high-angle grain boundaries. A wide range of materials can simply be deposited onto a variety of wafer-sized substrates. The films were deposited from solutions of the material, or from precursors of the material that readily converted to the final product with only volatile side products.

Spincoating also offers two avenues to highly ordered semiconductors for flexible electronics, displays, and solar cells. The materials can be spincoated onto flexible single-crystal-like metal foils. Or spincoating can be used to form a film such as NaCl that can then be used as a sacrificial template for epitaxial lift off of a free-standing semiconductor foil formed thereon by more conventional vapor deposition techniques.

In view of the above, it will be seen that the several objects of the invention are achieved and other advantageous results attained.

When introducing elements of the present invention or the preferred embodiments(s) thereof, the articles “a”, “an”, “the” and “said” are intended to mean that there are one or more of the elements. The terms “comprising”, “including” and “having” are intended to be inclusive and mean that there may be additional elements other than the listed elements.

As various changes could be made in the above compositions and methods without departing from the scope of the invention, it is intended that all matter contained in the above description and shown in the accompanying drawings shall be interpreted as illustrative and not in a limiting sense.

1. A process for forming an epitaxial film comprising:
spinning a substrate having an ordered crystal structure;
heating the substrate during spinning to a temperature between 70° C. and 150° C.;
dripping epitaxial film precursor solution onto the spinning substrate, where the precursor solution comprises inorganic film precursor material in a solvent; and
continuing the heating and spinning to remove the solvent and epitaxially grow the epitaxial film on the substrate.

2. The process of claim 1 wherein the precursor material comprises a material selected from the group consisting of Pbl₂, CsPbBr₃, NaCl, and Zn(II).

3. The process of claim 1 wherein the epitaxial film precursor solution comprises PbBr₂ and CsBr and the epitaxial film comprises CsPbBr₃.

4. The process of claim 1 wherein the epitaxial film precursor solution comprises PbBr₂ and CsBr dissolved in dimethyl sulfoxide solution and the epitaxial film comprises CsPbBr₃.

5. The process of claim 1 wherein the epitaxial film precursor solution comprises Pbl₂ and the epitaxial film comprises Pbl₂.

6. The process of claim 1 wherein the epitaxial film precursor solution comprises Pbl₂ dissolved in dimethylformamide solution and the epitaxial film comprises Pbl₂.

7. The process of claim 1 wherein the epitaxial film precursor solution comprises Zn ions and the epitaxial film comprises ZnO.

8. The process of claim 1 wherein the epitaxial film precursor solution comprises Zn ions in ammonium hydroxide and the epitaxial film comprises ZnO.

9. The process of claim 1 wherein the epitaxial film precursor solution comprises NaCl dissolved in water and the epitaxial film comprises NaCl.

10. The process of claim 1 wherein the epitaxial film precursor solution comprises Cd ions or Pb ions and the epitaxial film comprises CdS or PbS.

11. The process of claim 1 wherein the heating the substrate is to a temperature in the range of 70 to 130° C.

12. The process of claim 1 wherein the heating the substrate is to a temperature in the range of 70 to 90° C.

13. The process of claim 1 wherein the heating the substrate is to a temperature in the range of 90 to 130° C.

14. The process of claim 1 further comprising preheating the epitaxial film precursor solution to a temperature in the range of 70 to 150° prior to said dripping so that it is at said temperature during said dripping.

15. The process of claim 1 wherein:
the spinning the substrate comprises spinning a substrate based on SrTiO₃(100), Mica(001), Au/Si(111), or Au/Si(100) at a rotation rate between 400 and 3000 rpm;
the dripping epitaxial film precursor solution onto the spinning substrate comprises dripping a CsPbBr₃ solution;
the continuing the heating and spinning to remove the solvent and epitaxially grow the epitaxial film on the substrate is performed for between 25 and 180 seconds; and
the epitaxial film comprises CsPbBr₃.

16. The process of claim 1 wherein:
the spinning the substrate comprises spinning a substrate based on Au/Si(111) at a rotation rate between 400 and 3000 rpm;
the dripping epitaxial film precursor solution onto the spinning substrate comprises dripping a Pbl₂ solution;
the continuing the heating and spinning to remove the solvent and epitaxially grow the epitaxial film on the substrate is performed for between 25 and 180 seconds; and
the epitaxial film comprises Pbl₂.

17. The process of claim 1 wherein:
the spinning the substrate comprises spinning a substrate based on Ag(100) deposited on a Au(100) film on a Si(100) substrate at a rotation rate between 400 and 3000 rpm;
the dripping epitaxial film precursor solution onto the spinning substrate comprises dripping a NaCl solution;
the continuing the heating and spinning to remove the solvent and epitaxially grow the epitaxial film on the substrate is performed for between 25 and 180 seconds; and
the epitaxial film comprises NaCl.

18. The process of claim 1 wherein:
the spinning the substrate comprises spinning a substrate based on Au(111) at a rotation rate between 400 and 3000 rpm;
the dripping epitaxial film precursor solution onto the spinning substrate comprises dripping a Zn ion solution; and
the continuing the heating and spinning to remove the solvent and epitaxially grow the epitaxial film on the substrate is performed for between 25 and 180 seconds; and
the epitaxial film comprises ZnO.
